(19) United States
(12) Patent Application Publication
(10) Pub. No.: US 2009/0114963 A1
(43) Pub. Date: May 7, 2009

(54) Image Sensor and Method for Manufacturing the Same

(76) Inventor: Sung Hyok Kim, Hwaseong-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/256,531

(22) Filed: Oct. 23, 2008

(30) Foreign Application Priority Data
Nov. 5, 2007 (KR) 10-2007-0112158

(51) Int. Cl. H01L 31/00; H01L 21/00

(52) U.S. Cl. 257/292; 438/98; 257/E31.001; 257/E21.001

(57) ABSTRACT

An image sensor and a method for manufacturing the same are provided. The image sensor can include a lower interconnection for connecting transistor circuitry provided on a substrate to a photodiode element provided above the transistor circuitry, a lower electrode on the lower interconnection, and the photodiode element including an intrinsic layer and a second conductive type conduction layer. A dielectric can be disposed on the substrate exposing a top surface of the lower interconnection, and. the lower electrode can be disposed on the lower interconnection within the dielectric. The intrinsic layer can be disposed on the lower electrode, and the second conductive type conduction layer can be disposed on the intrinsic layer.

### CROSS-REFERENCE TO RELATED APPLICATION

The present application claims priority under 35 U.S.C. §119 of Korean Patent Application No. 10-2007-0112158, filed Nov. 5, 2007, which is hereby incorporated by reference in its entirety.

### BACKGROUND

In a related art horizontal type complementary metal oxide semiconductor (CMOS) image sensor, a photodiode is typically horizontally adjacent to a transistor on a substrate. Therefore, a pixel region of the substrate must be large enough to contain an additional portion for the photodiode region. As a result, the fill factor is reduced, and the resolution of the CMOS image sensor is limited.

Additionally, in a typical related art CMOS image sensor, image degradation often occurs due to crosstalk between pixels.

Moreover, according to related art horizontal-type CMOS image sensors, it is difficult to optimize the manufacturing process in which the photodiode and the transistor are manufactured at the same time.

Thus, there exists a need in the art for an improved image sensor and manufacturing method thereof.

### BRIEF SUMMARY

Embodiments of the present invention provide an image sensor and manufacturing method thereof in which a transistor region and a photodiode can be vertically integrated, and crosstalk between pixels can be inhibited.

Embodiments of the present invention also provide an image sensor and manufacturing method thereof capable of improving resolution and sensitivity.

Additionally, embodiments of the present invention also provide an image sensor and manufacturing method thereof in which a vertical-type photodiode can be utilized to inhibit defects from occurring in the photodiode.

In one embodiment of the present invention, an image sensor can comprise: a substrate including transistor circuitry and a lower interconnection; a dielectric on the substrate and exposing a top surface of the lower interconnection through a trench; a lower electrode on the lower interconnection and provided in the trench; an intrinsic layer on the lower electrode; and a second conductive type conduction layer on the intrinsic layer.

In another embodiment, a method for manufacturing an image sensor can comprise: forming a lower interconnection on a substrate having transistor circuitry; forming a dielectric on the substrate and exposing a top surface the lower interconnection; forming a lower electrode on the exposed lower interconnection; forming an intrinsic layer on the lower electrode; and forming a second conductive type conduction layer on the intrinsic layer.

The details of one or more embodiments are set forth in the accompanying drawings and the description below. Other features will be apparent to one of ordinary skill in the art from the description, the drawings, and the claims.

### BRIEF DESCRIPTION OF THE DRAWINGS

FIG. 1 is a cross-sectional view of an image sensor according to an embodiment of the present invention.

FIGS. 2 to 6 are cross-sectional views of a method for manufacturing an image sensor according to an embodiment of the present invention.

### DETAILED DESCRIPTION

Hereinafter, an image sensor and a method for manufacturing the same will be described in detail with reference to the accompanying drawings.

When the terms “on” or “over” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

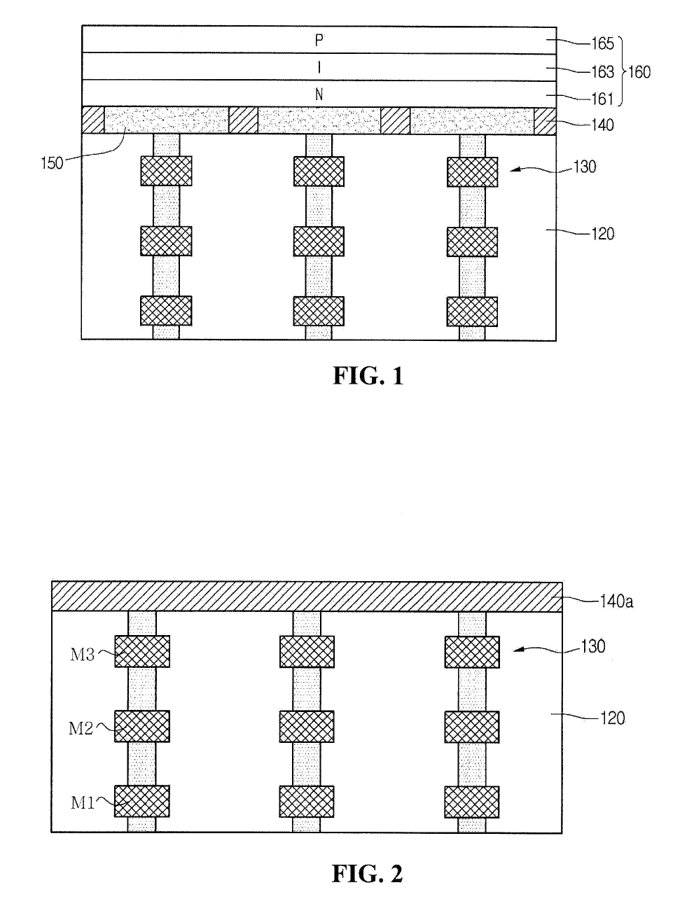

FIG. 1 a cross-sectional view of an image sensor according to an embodiment of the present invention.

An image sensor according to an embodiment can include a photodiode element (see e.g., reference 160) formed above transistor circuitry on a substrate (not shown). It will be apparent to one of ordinary skill in the art that the circuitry region can include structures such as reset transistors, drive transistors, transfer transistors, and so forth. The photodiode element (160) can be electrically connected to the transistor circuitry through a lower interconnection 130.

The lower interconnection 130 can be formed using any suitable number of metal layers and isolated by an interlayer dielectric 120. Although the figures illustrate three metal layers, this should not be construed as limiting. For example, embodiments can utilize a single metal layer or two metal layers. Alternatively, embodiments can utilize more than three metal layers. In addition, the interlayer dielectric 120 can be provided having a multi-layer structure.

Referring to FIG. 1, the image sensor can include a lower electrode 150 formed within a dielectric 140 provided above the lower interconnection 130. The dielectric 140 can be disposed on the substrate exposing the lower interconnection 130 (that is, such that the dielectric 140 allows the lower electrode 150 to electrically connect to the lower interconnection 130). In a specific embodiment, the lower electrode 150 can be disposed on the lower interconnection 130. To provide a photodiode element, an intrinsic layer 163 can be disposed on the lower electrode 150, and a second conductive type conduction layer 165 can be disposed on the intrinsic layer 163.

The dielectric 140 can be used to electrically separate the lower electrode 150 from another lower electrode 150 in an adjacent pixel.

The lower electrode 150 can be formed of any suitable material known in the art. For example, the lower electrode 150 can be formed of chromium (Cr), titanium (Ti), titanium nitride (TiN), tantalum (Ta), tantalum nitride (TaN), aluminum (Al), tungsten (W), or any combination thereof.

In one embodiment, the image sensor can also include a first conductive type conduction layer 161 under the intrinsic layer 163 and on the lower electrode 150. The intrinsic layer 163, the second conductive type conduction layer 165, and the first conductive type conduction layer 161 can serve as a photodiode 160.

In the image sensor according to an embodiment of the present invention, the lower electrode 150 can be separated from another lower electrode 150 in an adjacent unit pixel using the dielectric 140 to inhibit crosstalk between pixels.

A method for manufacturing an image sensor according to an embodiment of the present invention will now be described with reference to FIGS. 2 to 6.

Referring to FIG. 2, a circuitry region (not shown) including a lower interconnection 130 can be formed on a substrate (not shown). It will be apparent to one of ordinary skill in the art that the circuitry region can include structures such as reset transistors, drive transistors, transfer transistors, and so forth. In an embodiment, an interlayer dielectric layer 120 can be formed on the substrate, and the lower interconnection 130 can be formed within the interlayer dielectric layer 120.

In one embodiment, the lower interconnection 130 can include metal layers and plugs. The lower metal can include, but is not limited to, a first metal layer M1, a second metal layer M2, and a third metal layer M3.

A dielectric layer 140a can be formed on the substrate including the lower interconnection 130. For example, the dielectric layer 140a can include an oxide layer and/or a nitride layer.

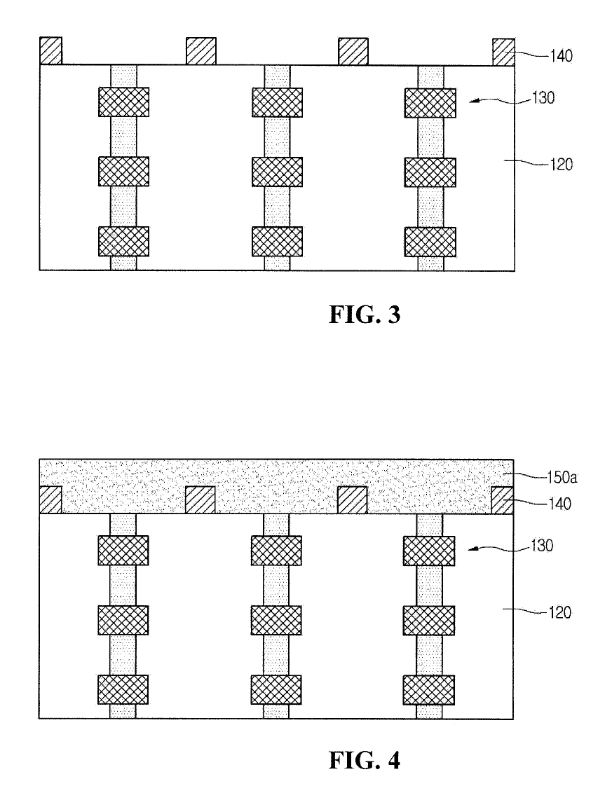

Referring to FIG. 3, the dielectric layer 140a can be selectively etched to expose the lower interconnection 130 and provide the dielectric 140. The exposed regions can correspond to each unit pixel area. The etching pattern of the dielectric layer 140a can be a photodiode pattern.

Referring to FIG. 4, a metal 150a for the lower electrode 150 can be formed on the dielectric 140. The metal 150a for the lower electrode 150 can be formed of any suitable material known in the art, for example, Cr, Ti, TiN, Ta, TaN, Al, W, or any combination thereof.

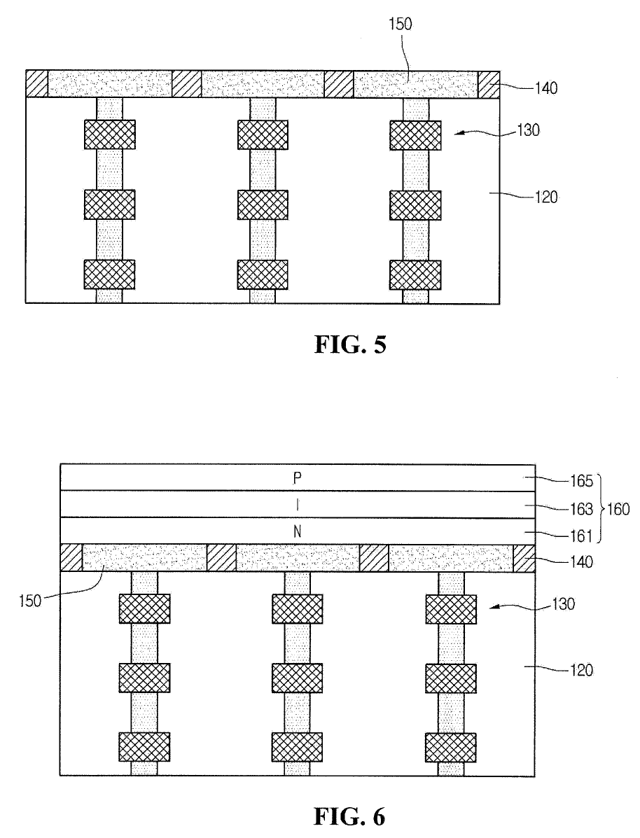

Referring to FIG. 5, the metal 150a for the lower electrode 150 can be planarized to form the lower electrode 150 separated from other lower electrodes 150 in adjacent unit pixels. The metal 150a can be planarized by any suitable method known in the art. For example, the metal 150a can be blanket-etched in chlorine (Cl₂) and oxygen (O₂) atmosphere using a dry etching process and planarized to form the lower electrode 150.

Referring to FIG. 6, an intrinsic layer 163 can be formed on the lower electrode 150. In one embodiment, the intrinsic layer 163 can be formed of any suitable material known in the art, such as amorphous silicon. Additionally, the intrinsic layer 163 can be formed using any suitable method known in the art. For example, the intrinsic layer 163 can be formed using a chemical vapor deposition (CVD) method such as a plasma enhanced chemical vapor deposition (PECVD) method. In one embodiment, the intrinsic layer 163 can be formed of amorphous silicon using silane (SiH₄) gas by a PECVD method.

In an embodiment, a first conductive type conduction layer 161 can be formed after forming the lower electrode 150 and before forming the intrinsic layer 163. The first conductive type conduction layer 161 can be formed of any suitable material known in the art, such as n-doped amorphous silicon. Additionally, the first conductive type conduction layer 161 can be formed using any suitable method known in the art. For example, the first conductive type conduction layer 161 can be formed using a chemical vapor deposition (CVD) method such as a plasma enhanced chemical vapor deposition (PECVD) method. In one embodiment, the first conductive type conduction layer 161 can be formed of n-doped amorphous silicon using silane (SiH₄) gas mixed with phosphorus by a PECVD method.

A second conductive type conduction layer 165 can be formed on the intrinsic layer. The second conductive type conduction layer 165 and the intrinsic layer 163 can be formed in a continuous process, but embodiments of the present invention are not limited thereto. The second conductive type conduction layer 165 can be formed of any suitable material known in the art, such as p-doped amorphous silicon. Additionally, the second conductive type conduction layer 165 can be formed using any suitable method known in the art. For example, the second conductive type conduction layer 165 can be formed using a CVD method such as a PECVD method. In one embodiment, the second conductive type conduction layer 165 can be formed of p-doped amorphous silicon using silane (SiH₄) gas mixed with boron by a PECVD method.

In embodiments in which a first conductive type conduction layer 161 is formed, the intrinsic layer 163, the second conductive type conduction layer 165, and the first conductive type conductive layer 161 can serve as a PIN photodiode 160. Of course, the first conductive type conduction layer 161 can be omitted by using the lower electrode 150 (forming a P-I-M photodiode structure).

In an embodiment, although not shown, a top metal, a color filter, and/or a microlens can be formed on the second conductive type conduction layer 165.

In the image sensor and the method for manufacturing the same according to embodiments of the present invention, the transistor circuitry and the photodiode can be vertically arranged. Thus, the fill factor can approach nearly 100%.

Additionally, since the lower electrode can be separated by the dielectric from another lower electrode in an adjacent unit pixel, crosstalk between the pixels can be inhibited. Also, the sensitivity of the image sensor can be higher than that of a related art image sensor having the same pixel size because of the vertical integration of the transistor circuitry and the photo diode.

Moreover, the size of the semiconductor device can be decreased, and the manufacturing cost can be reduced. In addition, the vertical-type photodiode can be adopted to inhibit typical defects from occurring in the photodiode when the photodiode is formed in the substrate.

Any reference in this specification to “one embodiment,” “an embodiment,” “exemplary embodiment,” etc., means that a particular feature, structure, or characteristic described in connection with the embodiment is included in at least one embodiment of the disclosure. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with others of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a lower interconnection on a substrate including transistor circuitry;
a dielectric on the substrate and comprising a trench exposing a top surface of the lower interconnection;
a lower electrode on the exposed lower interconnection and within the trench of the dielectric;
an intrinsic layer on the lower electrode; and
a second conductive type conduction layer on the intrinsic layer.

2. The image sensor according to claim 1, wherein the lower electrode is electrically separated by the dielectric from an adjacent lower electrode in an adjacent unit pixel.

3. The image sensor according to claim 1, wherein the lower electrode comprises chromium (Cr), titanium (Ti), titanium nitride (TiN), tantalum (Ta), tantalum nitride (TaN), aluminum (Al), tungsten (W), or any combination thereof.

4. The image sensor according to claim 1, wherein the lower electrode is provided corresponding to a unit pixel.

5. The image sensor according to claim 1, further comprising a first conductive type conduction layer on the lower electrode and under the intrinsic layer.

6. The image sensor according to claim 5, wherein the first conductive type conduction layer is provided directly on a top surface of the lower electrode and a top surface of the dielectric.

7. A method for manufacturing an image sensor, comprising:
forming a lower interconnection on a substrate;
forming a dielectric on the substrate, exposing a top surface of the lower interconnection;
forming a lower electrode on the lower interconnection;
forming an intrinsic layer on the lower electrode; and
forming a second conductive type conduction layer on the intrinsic layer.

8. The method according to claim 7, wherein forming the dielectric comprises:
depositing dielectric on the substrate; and
selectively etching the dielectric to expose the top surface of the lower interconnection.

9. The method according to claim 8, wherein selectively etching the dielectric comprises performing an etching process to form a trench corresponding to a region for a unit pixel.

10. The method according to claim 9, wherein the dielectric electrically separates the lower electrode from an adjacent lower electrode.

11. The method according to claim 7, wherein the lower electrode comprises Cr, Ti, TiN, Ta, TaN, Al, W, or any combination thereof.

12. The method according to claim 7, wherein forming the lower electrode on the lower interconnection comprises:
depositing a metal for the lower electrode on the exposed lower interconnection and the dielectric; and
planarizing the metal for the lower electrode to expose a top surface of the dielectric.

13. The method according to claim 12, wherein planarizing the metal for the lower electrode comprises dry etching the metal for the lower electrode in a chlorine (Cl₂) and oxygen (O₂) atmosphere.

14. The method according to claim 12, wherein the metal for the lower electrode comprises Cr, Ti, TiN, Ta, TaN, Al, W, or any combination thereof.

15. The method according to claim 7, further comprising forming a first conductive type conduction layer on the lower electrode before forming the intrinsic layer.

16. The method according to claim 15, wherein forming the first conductive type conduction layer comprises performing a PECVD method using silane (SiH₄) gas mixed with phosphorus.

17. The method according to claim 7, wherein forming the intrinsic layer comprises performing a plasma enhanced chemical vapor deposition (PECVD) method using silane (SiH₄) gas.

18. The method according to claim 7, wherein forming the second conductive type conduction layer comprises performing a PECVD method using silane (SiH₄) gas mixed with boron.
